(19) United States
(12) Patent Application Publication
(10) Pub. No.: US 2007/0153474 A1
(43) Pub. Date: Jul. 5, 2007

(54) Cooling system and method of use

(76) Inventors: Jesper Alexander Andersen, Lake Hiawatha, NJ (US); Thomas Francis Craft, Hackettstown, NJ (US)

Correspondence Address: HARNESS, DICKEY & PIERCE, P.L.C., P.O. BOX 8910, RESTON, VA, 20195, US

(21) Appl. No.: 11/320,478

(22) Filed: Dec. 29, 2005

(51) Int. Cl. H05K 7/20

(52) U.S. Cl. 361/691

(57) ABSTRACT

In one embodiment, the cooling system includes both a primary cooling system configured to move a first cooling fluid across a major surface of the circuit boards and a secondary cooling system configured to move a second cooling fluid across at least one primary or targeted component mounted on one of the circuit boards. The secondary cooling system provides enhanced forced convective cooling of the primary component and provides a degree of redundancy for the targeted components. Also disclosed are methods of cooling electronic devices using such cooling systems.

### REFERENCE TO RELATED CASES

The invention detailed below is related in certain aspects relating to nozzle design and configuration to the inventor's copending U.S. patent application entitled JET IMPINGEMENT COOLING APPARATUS AND METHOD, the contents of which is incorporated herein, by reference, in its entirety.

### TECHNICAL FIELD OF THE INVENTION

The present invention is directed to cooling systems for cooling electronic components and, more specifically, to integrated secondary cooling systems that can selectively increasing the cooling of electronic components and that are suitable for use with board mounted electronic components and enclosures holding a plurality of boards and methods of using such cooling systems.

### BACKGROUND OF THE INVENTION

Designers of electronic circuits will typically incorporate one or more methods for controlling heat generated by the electronic components that comprise the circuit into their designs. Unless sufficiently controlled, the heat generated by the electronic components during use will tend to result in premature component and/or circuit failure. Adequate temperature control, therefore, is a key factor for maintaining satisfactory circuit reliability. The preferred method to controlling temperature is to dissipate the excess heat into the ambient air surrounding the electronic circuit at a rate sufficient to maintain the component temperatures at a level below which unacceptable levels of damage can occur.

A conventional method for suppressing temperature increase within an electronic component is to associate the heat generating components with heat dissipation devices, such as heat sinks. The heat dissipation device absorbs excess heat from the component and provides a more efficient transfer of the excess heat into the surrounding ambient air. In most cases, the heat generating component will be mounted directly to the heat dissipation device to more efficiently remove the excess heat from the component.

Although traditional heat sinking methods can be successful in some instances, the problems associated with temperature control have become more pronounced as electronic circuits have become more complex. Such circuit complexity often results in a circuit that requires a larger number of components, which frequently are more powerful and that, consequently, can generate even more heat. The problem is further complicated by the fact that lower profile and more compact electronic systems have become the preferred choice of customers. This means that space must be found in such low profile, compact systems for both the electronic components that make up the circuit as well as the heat dissipation devices that such components require in order to prevent heat related damage. In short, as the power density of circuits has increased, the use of traditional or conventional finned heat sinks may no longer adequately address the corresponding heat dissipation requirements or may be unsuitable in light of the demanding board-to-board spacing requirements resulting from low-profile and/or mezzanine level boards.

In some instances, heat management problems have been resolved by using active, rather than passive, systems to control temperature build up. For example, certain board mounted electronic components that generate large amounts of heat can have an active cooling device, such as a small fan, dedicated solely to the device. In those situations where a fan is used as the active device, the fan is mounted directly on the component and improves cooling by moving more ambient air over the component. Using a fan in this manner can sometimes provide more efficient cooling in less space than conventional heat sink approaches.

The demands on such dedicated fans have, however, been increasing as they are applied in more challenging applications that have required that the fans operate much higher in their performance band to maintain adequate cooling. For example, systems that operated adequately with fans operating at about 20 W can now require fans running in the 150-180 W range. Meeting these operational demands while still providing sufficient longevity has tended to increase the cost of the fans utilized in such applications and increased the risk to the cooled components in the event of fan failure.

Notwithstanding the benefits achieved with active cooling devices, such as fans, there continues to be a demand for improved temperature control for sensitive semiconductor components. These demands continue to lead those skilled in the art of thermal management in their efforts to develop improved heat control methods for addressing heat control for heat generating electronic components arrayed on a board and potentially installed in an electronics cabinet or equipment shelf subjected to extreme environmental heating contributions including, for example, control circuits at power distribution stations.

### SUMMARY OF THE INVENTION

Example embodiments of the invention provide systems suitable for new installations and retrofit applications that provide for increased spot cooling of one or more board-mounted components and thereby improving the overall reliability of the cooling system and the electronic components protected by the cooling system.

Example embodiments of the invention include cooling systems for cooling electronic devices arrayed on a plurality of circuit boards comprising at least a primary cooling system configured to move a first cooling fluid across a major surface of the circuit boards to provide forced convective cooling of components mounted on the circuit boards and a secondary cooling system configured to move a second cooling fluid across at least one primary component mounted on one of the circuit boards to provide enhanced forced convective cooling of the primary component.

Example embodiments of the invention include secondary cooling systems having a primary manifold or plenum for receiving the second cooling fluid, typically air, that extends adjacent an edge of a plurality of circuit boards, a secondary manifold for receiving the second cooling fluid from the primary manifold; a runner for receiving the second cooling fluid from the secondary manifold; a nozzle assembly provided at a distal end of the runner for directing the second cooling fluid onto a surface of the primary component; and a means for pressurizing the second cooling fluid before it enters the primary manifold, for example, a blower or a fan.

The secondary cooling systems according to example embodiments of the invention will typically exhibit a configuration in which one primary manifold, or a relatively small number of primary manifolds, are used to supply or distribute the second cooling fluid to a relatively larger number of secondary manifolds. The secondary manifolds can include, or can be configured for the subsequent and selective attachment of, one or more runners through complementary attachment assemblies including, for example, friction fit, threaded fittings, thermally fusable fittings and quick disconnect fittings of various configurations.

The runners may be configured as relatively fixed components or they may be provided with one or more regions that allow them to be shortened and/or elongated, rotated, deflected and/or bent in order to compensate for some degree of initial misalignment between the targeted component and the nozzle assembly. The runners and the runner ports or other complementary structures may be provided with first attachment structures and second attachment structures that cooperate to form a fluid tight connection between the secondary manifolds and the runners.

For example, in some embodiments the runner ports may be provided with a valve assembly that normally operates to seal the runner ports and prevent the release of the second cooling fluid from the secondary manifold that cooperates with a second attachment structure on the runner that will open the valve assembly as the runner is attached to the runner port. Alternatively, attachment points may be provided with a cap assembly that must be removed before the additional distribution component(s) may be attached to extend the passage for the secondary cooling fluid.

In addition to the increased convective cooling resulting from the targeted application of the second cooling fluid, the cooling system may also include a heat exchange assembly for reducing the temperature of the second cooling fluid between the time it enters the cooling system and the time it exits the nozzle assembly to increase the cooling capacity of the system. The heat exchange assembly may include, for example, a fluid based heat exchanger, an evaporative cooling system and/or a thermoelectric surface.

The invention also relates to example embodiments of methods of operating cooling systems as described herein for the purpose of cooling electronic components, particularly those mounted on a circuit pack assembly within an equipment shelf. In particular, the use of at least two complementary cooling systems for certain protected components provides a degree of redundancy whereby, should one cooling system become inoperable, the remaining cooling system will continue to provide at least reduced cooling for the protected components. This continued cooling can provide additional time for instituting shutdown or other remedial procedures while still maintaining a degree of protection for the components.

Further, depending on the size and thermal load of a particular component, the runner and nozzle combination can be tailored to some degree to provide a range of cooling effectiveness suitable for the component at issue rather than subjecting the entire circuit board to a cooling operation actually directed at only a relative small number of the components arrayed on the circuit board. Also, because the secondary cooling system may be utilized to increase the cooling of the more sensitive components, the demands on the primary cooling system may be reduced. As a result of the reduced demands on the primary cooling system, the capacity of the primary cooling system may be reduced by, for example, utilizing smaller components or simply by running the existing components at reduced power. Reducing the demands on the primary cooling system will also tend to reduce power consumption and ambient noise, increase the longevity of fans, blowers or other active components and maintain sufficient general cooling capacity.

### BRIEF DESCRIPTION OF THE DRAWINGS

For a more complete understanding of the present invention, reference is now made to the following descriptions taken in conjunction with the accompanying drawings, in which:

FIG. 1 illustrates an orthogonal view of certain components arranged in an example embodiment of a cooling system according to the invention and suitable for use as a secondary cooling system in combination with a primary cooling system for cooling one or more board mounted devices;

FIG. 2 illustrates another orthogonal view of certain board-based components arranged in an example embodiment of a cooling system according to the invention and suitable for cooling one or more board mounted devices;

FIG. 3A illustrates a frontal view of a plurality of circuit packs or boards mounted in an equipment shelf or cabinet;

FIG. 3B is a cross-sectional view of the equipment shelf of FIG. 3A taken along plane 3B-3B to reveal an example circuit pack and components and structures associated with both a primary cooling system and a secondary cooling system;

FIG. 4A illustrates a plan view of a certain components arranged on an example circuit pack generally corresponding to those illustrated in FIGS. 1, 2 and 3B;

FIG. 4B illustrates a cross-sectional view of certain components arranged in an example embodiment of a cooling apparatus according to the invention and suitable for cooling one or more board mounted devices generally corresponding to FIG. 4A taken along plane 4B-4B;

FIG. 4C illustrates a partial cross-sectional view of the indicated portion of the example embodiment of FIG. 4B showing additional detail with regard to certain of the components;

FIG. 5A illustrates an orthogonal view of an example embodiment of a modular configuration of an equipment shelf including a plurality of circuit packs; and

FIG. 5B illustrates an orthogonal view of an example embodiment of a modular configuration as shown in FIG. 5A after assembly.

These drawings have been provided to assist in the understanding of the exemplary embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity.

Those of ordinary skill in the art will also appreciate that a range of alternative configurations have been omitted simply to improve the clarity and reduce the number of drawings. Those of ordinary skill will appreciate that certain of the various process steps illustrated or described with respect to the exemplary embodiments may be selectively and independently combined to create other methods useful for manufacturing semiconductor devices without departing from the scope and spirit of this disclosure.

### DETAILED DESCRIPTION OF EXAMPLE EMBODIMENTS

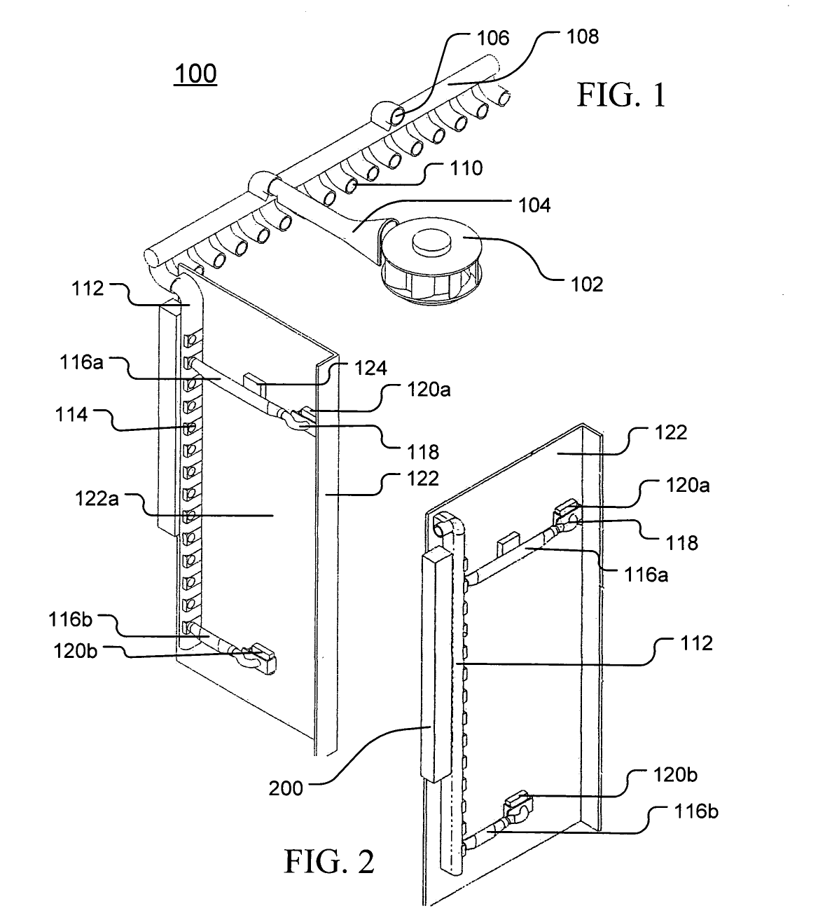

As illustrated in FIG. 1, the orthogonal view of an example embodiment of a cooling apparatus 100 according to the invention that includes a fan or blower 102 for forcing an ambient fluid, typically air, into a passage 104 that is connected through an appropriate fitting or structure 106 to a primary manifold 108. The primary manifold 108 can be configured to distribute or direct the gas flow in one or more directions generally perpendicular to the direction of flow through the passage 104. The primary manifold 108 may be provided with a series of appropriate fittings or structures 110 for directing a portion of the gas flow from the primary manifold 108 into a secondary manifold 112. Each secondary manifold 112 may be associated with one or more circuit boards, cards or circuit pack assemblies 122 on which a number of heat-generating devices, components 120a, 120b (collectively 120) and 124, e.g., semiconductor devices, that will benefit from cooling are mounted.

The secondary manifold 112 may be provided with a series of runner ports 114 that are configured for the attachment of a proximal end of a runner 116a, 116b (collectively 116) through which the gas can be directed to a nozzle assembly 118 positioned adjacent one or more devices 120 that will benefit from additional cooling. Example embodiments of nozzle assemblies 118 according to the invention orient and direct a flow of air or other fluid onto a surface of the corresponding devices 120.

The nozzle assemblies 118 are also configured with an open structure that allows the components or devices 120 to be cooled by forced or natural convection provided by a primary cooling system. This primary cooling may then be supplemented for selected components with a secondary cooling system 100 according to an example embodiment of the invention that provides forced convective cooling by the fluid(s) issuing from the nozzle 118. The combination of both a primary and a secondary cooling system 100 also provides some redundancy for at least the selected components 120. As will be appreciated by those skilled in the art, the devices 120, 124 may also be provided with heat sinks (not shown) or other structures that will tend to increase the heat transfer that can be achieved by the cooling system(s).

As noted above, example embodiments of the cooling system may be configured for new installation and may have the various components of the cooling system arranged on the circuit board or circuit pack assembly 122 before insertion into an equipment shelf. The preinstalled components, for example, the nozzle assembly 118, runner 116 and possibly the secondary manifold 112 will be configured to cooperate with and engage complementary structures provided within the equipment shelf including, for example, a primary manifold 108, fittings 110 and/or runner ports 114 depending on the specific configuration.

For example, in one example embodiment, as the circuit board or circuit pack assembly 122 is being installed in the equipment shelf, a portion of the runner 116 contacts and punctures or displaces a plug, cap 128a or a valve assembly (not shown) provided at the runner ports 114 and configured for preventing loss of cooling fluid through runner ports 114 to which no runner 116 has been attached. After puncturing or displacing the structure(s) that normally close the runner ports 114 to prevent loss of the cooling fluid, the cooperating portions of the runner 116 and the runner port 114 will tend to form a generally fluid-tight seal when the board 122 reaches the fully installed position and will direct the cooling fluid from the secondary manifold 112 into and along the runner 116 to the nozzle assembly 118.

For instance, in another example embodiment, the complementary components used to assembly the secondary cooling system 100 may be the secondary manifold 112 and the fitting or structure 110 through which the secondary manifold 112 may be connected to the primary manifold 108. As will be appreciated by those skilled in the art, although illustrated as having a single attachment point, the fitting or structure 110 and the secondary manifold 112 may be configured to provide for a plurality of connection points to provide for increased flow area and perhaps reduce the pressure drop within or improve the flow through the system between the fan(s) or blower(s) 102 and the cooled components 120.

Although the runner ports 114 and the runners 116 have been described as having a one-to-one correspondence, those skilled in the art will appreciate that in some applications increased flow could be achieved by connecting a single runner 116 to a plurality of runner ports 114. Similarly, depending on the particular demands of an application, a single runner 116 may be configured to include a plurality of nozzle assemblies 118 directed to multiple components 120 on the same board and/or on closely adjacent boards, for example, mezzanine boards (not shown).

The complementary structures, for example, a proximal portion of a runner 116a and a corresponding runner port 114, should generally form a fluid-tight seal to reduce losses of cooling fluid from the system before it reaches the cooled components. As will be appreciated by those skilled in the art, the connection(s) between complementary components of the system may assume a number of configurations depending on, for example, the connecting components, the materials used, the ease of access to the attachment point(s) and the thermal demands on the cooling system. As will also be appreciated by those skilled in the art, similar considerations will typically guide the sizing of the components, the configuration of the nozzle assemblies, the operating parameters of the blower, fan or other device 102 used to pressurize the cooling fluid entering or within (not shown) the cooling system conduits 104, 108, 112, 116 relative to the ambient pressure.

The nozzle assembly 118 may also be provided with a variety of attachment structures (not shown) that cooperate with corresponding structures provided adjacent the targeted component 120 for generally fixing the position of the nozzle assembly 118 above the targeted component 120.

By improving the cooling of some of the more sensitive components, the example embodiments of the system allow the associated fan(s) and/or blower(s) 102, 126 to be operated at lower power and/or lower rpm which, in turn, can provide improvements including, for example, increased average service life, reduced power consumption and reduced ambient noise.

As illustrated in FIG. 2, another orthogonal view of an example embodiment of the secondary cooling system 100 illustrates those components that may be attached to the circuit pack or board 122 as discussed above in relation to FIG. 1. The modified orientation provided in FIG. 2 more clearly shows the back plane connector or connector assembly 200 that will cooperate with a corresponding structure (not shown) provided in the equipment shelf to provide, for example, power and signal connections for the components 120, 124 arrayed on the circuit pack 122.

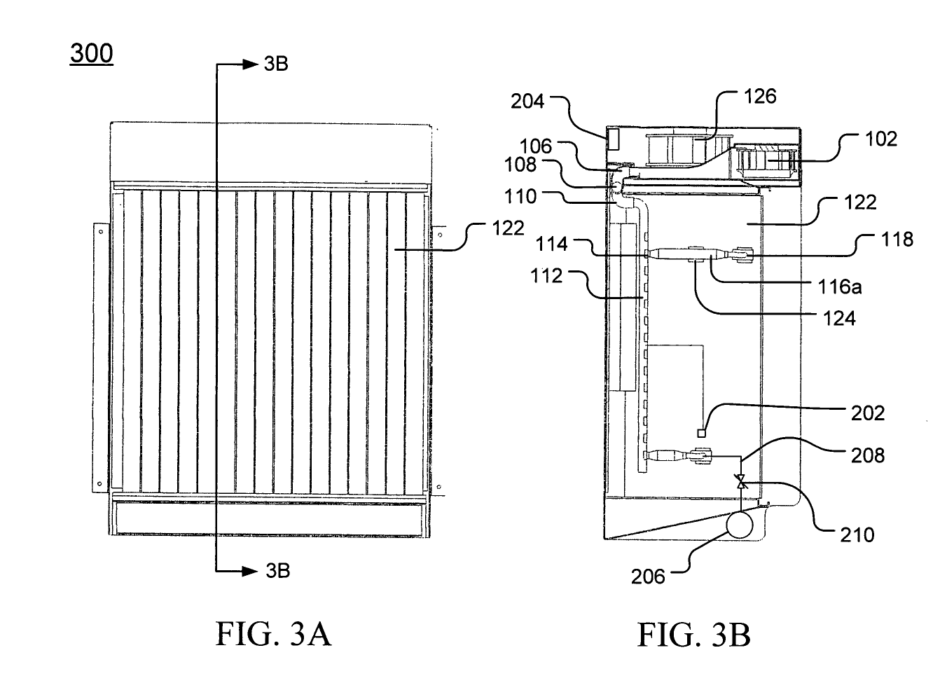

As illustrated in FIG. 3A, a plurality of boards or circuit packs 122 may be assembled in a single equipment shelf 300. As illustrated in FIG. 3B, the cooling system 100 described in connection with the example embodiments shown in FIGS. 1 and 2 may be arranged to cooperate with a primary cooling system utilizing other fan(s) or blower(s) 126 and ducting or deflecting elements for moving a cooling fluid, typically air, across the major surface 122a of the circuit board or circuit pack assembly 122. Accordingly, all of the components mounted on a circuit pack 122 will typically be cooled by a primary cooling system while those components identified as needing or targeted for secondary cooling will also be cooled by a secondary cooling system 100 according to the example embodiment illustrated in FIGS. 1 and 2.

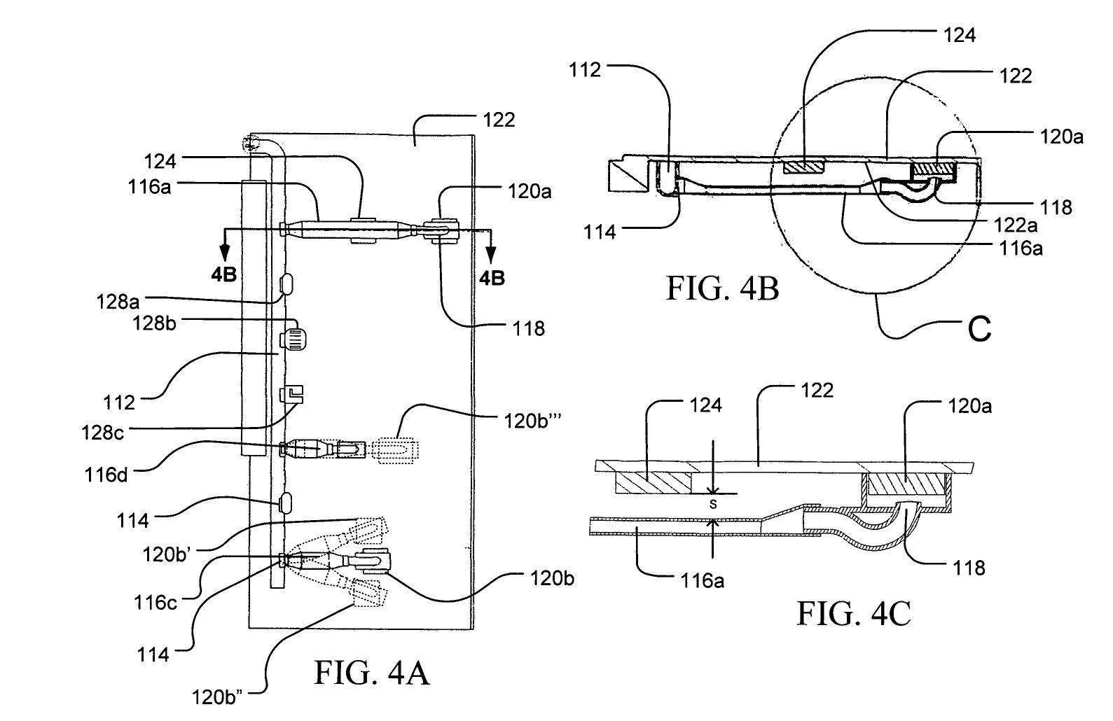

As illustrated in FIG. 4A, the basic components associated with an example embodiment of a cooling system 100 according to the invention may be configured to increase the flexibility and range of applications for the cooling system 100. In particular, the runner ports 114 may be normally sealed with one or more caps 128a, 128b or valve structures (not shown). Runners 116 may be attached to runner ports 114 by piercing a fixed cap 128a with a portion of the runner 116 or suitable tool (not shown) or by removing a removable cap 128b, for example, a threaded cap, by hand or with a suitable tool (not shown) and attaching a runner 116 to the opened runner port 114.

Once the cap 128a, 128b has been pierced or removed, a portion of the runner 116, which may include a first attachment structure (not shown), will be inserted into the opening formed and will typically cooperate in some fashion with the remaining portion of the cap 128a, the runner port 114 and/or the secondary manifold 112 to form a fluid tight seal. For example, a fitting 128c may be associated with a runner port 114 and thereby provide a second attachment structure that will cooperate with a first attachment structure (not shown) on an a proximal end of a runner 116 for establishing a secure, but optionally removable, attachment between the runner 116 and the secondary manifold 112.

As illustrated in FIG. 4B, in some instances, the runner 116 will need to extend across one or more components 124 in order to reach the desired or targeted component 120a. As will be appreciated by those skilled in the art, the sizing and configuration of the runners 116 will typically be taken into account in order to ensure that effect of the runners 116 on the fluid flow across the major surface(s) 122a of the circuit pack assemblies 122 to ensure that the flow of the cooling fluid is not unduly obstructed. Indeed, in some configurations the placement, separation distance S (as indicated in FIG. 4C) and shape of the portion of the runner body 116 arranged over a non-targeted component 124 (i.e., a component mounted on the circuit pack assembly 122 that does not, at present, warrant its own nozzle assembly) may actually be utilized to increase the local velocity of the cooling fluid as it flows around the obstruction, i.e., the portion of runner 116 adjacent component 124, thereby improving the forced convective cooling of the non-targeted component.

As will be appreciated, new installations incorporating a cooling apparatus or system that incorporates certain features and functionality of the example embodiments detailed above allow for complementary design of the circuit pack assemblies and the cooling assembly components. However, as noted above, the example embodiment of the secondary cooling system 100 described with reference to, for example, FIGS. 1, 2 and 3B, may incorporate one or more modified components adapted to simplify the retrofitting of a secondary cooling system. The design and selection of such retrofit components will typically include consideration of, for example, the connecting components and assembly, the materials used, the ease of access to the attachment point(s) and the thermal demands on the cooling system.

In particular, as illustrated in FIG. 4A, a secondary cooling system 100, as illustrated in FIG. 1, may adapted for retrofit installation by utilizing modified runners 116c that incorporate one or more sections (not shown) that allow for some deflection of the runners 11 6c up or down (as indicated by the “up” and “down” deflected positions suggested by the dashed outlines) relative to the position of the corresponding runner port 114 to which the runner 116c is attached. By providing for deflection of the runner 116c, the nozzle assembly 118 may be positioned above a targeted component 120b′, 120b″ that is vertically offset from an aligned position indicated by component 120b.

Similarly, as also illustrated in FIG. 4A, a runner 116d may be provided with one or more sections or elements that allow the length of the runner 114 to be adjusted in and out (as indicated by the “out” position suggested by the dashed outline) relative to a corresponding runner port 114 in order to more precisely position the nozzle assembly 118 above the targeted component 120b′″. As will be appreciated by those skilled in the art, the use of relative terms up and down, left and right, top and bottom are simply for convenience in describing the illustrated example embodiments and are not intended to imply that any particular orientation is required or preferred. Similarly, those skilled in the art will appreciate that the range of adjustment provided by a modified runner 116, for example, runners 116c and 116d, will depend on the materials selected, the structures utilized and the dimensions of the modified runner 116 and may, therefore, be configured to provide for a relatively wide range of adjustment or a relatively limited range of adjustment as desired for a particular application.

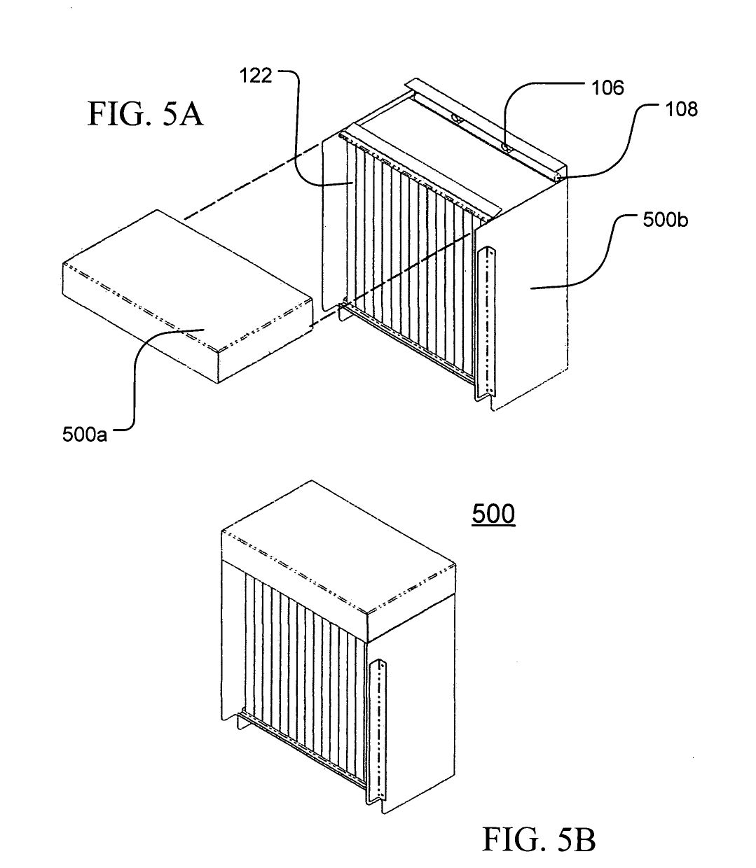

As illustrated in FIGS. 5A and 5B, the equipment shelf may be configured as a series of modular components in order to simplify installation and maintenance activities. In the example embodiment illustrated in FIGS. 5A and 5B, the blowers, fans and initial ducting structure may be provided in a modular upper unit 500a that may be easily attached to a corresponding modular base unit 500b to form a composite equipment shelf unit 500. In the example embodiment illustrated in FIG. 5A, the docking portion of the modular base unit 500b includes appropriate fittings or ports 106 that will receive or otherwise connect to corresponding elements (not shown) provided in the modular upper unit 500a to form an embodiment of the cooling system as illustrated in FIG. 1.

Although the invention has been described with respect to a secondary cooling system 100 and a method for providing auxiliary cooling for targeted components 120 on a circuit pack 122, the cooling system 110 may include additional components including, for example, an emergency cooling system for protecting at least the most critical components. As illustrated in FIG. 3B, an example embodiment of an emergency cooling system incorporates a temperature sensor 202, for example, a thermocouple or IR thermal detector, for monitoring the temperature of the protected, endangered and/or primary components 120 during operation of the component and providing corresponding signals to a controller 204 reflecting the status of the protected components.

In the event that the controller 204 determines, for example, that an overtemp state is present on a protected component 120 it can trigger one or more remedial actions such as increasing the cooling fluid flow to the endangered component 120, decreasing the temperature of the cooling fluid, triggering an alarm, initiating a safe shutdown procedure and/or applying a supplemental cooling fluid to the endangered device. The supplemental cooling fluid may be applied as a cold gas, e.g., tetrafluoroethane or other suitable compound (s) released from a pressurized container 206 through a line 208 controlled by a valve 210. Alternatively, the supplemental cooling fluid may be applied as a liquid that will evaporate on contact with the hot surfaces of the endangered component to provide evaporative cooling. The reservoir(s), valves, conduits and passages 206, 208, 210 associated with the supplemental cooling fluid may be configured to cooperate with the secondary cooling system 100 by, for example, providing an outlet for the supplemental cooling fluid within the nozzle assembly 118 and thereby utilize the existing structure and positioning relative to the protected component 120.

Although the invention has been described in connection with certain exemplary embodiments and configurations, it will be evident to those of ordinary skill in the art that many alternatives, modifications, and variations may be made to the disclosed methods in a manner consistent with the detailed description provided above. Also, it will be apparent to those of ordinary skill in the art that certain aspects of the various disclosed exemplary embodiments could be used in combination with aspects of any of the other disclosed embodiments or their alternatives to produce additional embodiments of the invention that depart from the representative configurations illustrated herein.

Indeed, it is anticipated and expected that those skilled in the art will adapt the illustrated embodiments to provide more suitable configurations for particular enclosures, intended uses and/or performance requirements. Accordingly, it is intended that all such alternatives, modifications and variations that fall within the spirit of the invention are to be encompassed within the scope of the invention.

We claim:

1. A system for cooling components arrayed on a plurality of adjacent circuit boards comprising:
a primary cooling system configured to move a first cooling fluid across major surfaces of the circuit boards and thereby provide forced convective cooling of the components mounted on the major surfaces;
a secondary cooling system configured to move a second cooling fluid across a primary component mounted on the major surface of one of the circuit boards and thereby provide enhanced forced convective cooling of the primary component.

2. The system for cooling electronic devices according to claim 1, wherein the secondary cooling system comprises:
a primary manifold for receiving the second cooling fluid;
a secondary manifold for receiving the second cooling fluid from the primary manifold;
a runner for receiving the second cooling fluid from the secondary manifold;
a nozzle assembly attached to the runner for directing the second cooling fluid onto a surface of the primary component; and
an apparatus for forcing the second cooling fluid into the primary manifold.

3. The system for cooling electronic devices according to claim 2, wherein
the primary manifold supplies the second cooling fluid to a plurality of secondary manifolds;
the secondary manifolds are configured to allow for the attachment of a plurality of runners.

4. The system for cooling electronic devices according to claim 3, wherein
the secondary manifolds include a plurality of runner ports having a first attachment structure; and
the runners include a second attachment structure, the first and second attachment structures cooperating to form a fluid tight connection between the secondary manifolds and the runners.

5. The system for cooling electronic devices according to claim 4, wherein
the runner ports include a valve assembly that normally operates to seal the runner ports; and
the second attachment structure opens the valve assembly as the runner is attached to the runner port.

6. The system for cooling electronic devices according to claim 3, wherein
the runners are configured to be selectively deflected within a plane generally parallel to the major surface of the circuit boards.

7. The system for cooling electronic devices according to claim 6, wherein
the runner includes a deflecting structure selected from a group consisting of a flexible member, an elastic member, a bellows member and a pivoting member.

8. The system for cooling electronic devices according to claim 3, wherein
the runner has a length that may be selectively varied between a minimum length and a maximum length.

9. The system for cooling electronic devices according to claim 8, wherein
the length of the runner is adjusted using a structure selected from a group consisting of an elastic member, a bellows segment, a telescoping region and a threaded segment.

10. The system for cooling electronic devices according to claim 2, wherein
the nozzle assembly is configured for attachment to the major surface of the circuit board adjacent the primary component.

11. The system for cooling electronic devices according to claim 10, wherein
a first attachment component is provided on the nozzle and a second attachment component is provided on the major surface of the circuit board adjacent the primary component, the first and second attachment components cooperating to attach the nozzle to the circuit board.

12. The system for cooling electronic devices according to claim 2, wherein
the second cooling fluid moves across a heat transfer structure in thermal contact with the primary component, the heat transfer structure increasing an effective convective area of the primary component.

13. The system for cooling electronic devices according to claim 2, further comprising:
a cooling apparatus for removing heat from the second cooling fluid before the second cooling fluid exits the nozzle.

14. The system for cooling electronic devices according to claim 13, wherein
the cooling apparatus includes a device selected from a group consisting of a fluid based heat exchanger and a thermoelectric surface.

15. The system for cooling electronic devices according to claim 2, wherein
the apparatus for forcing the second cooling fluid into the primary manifold includes a device selected from a group consisting of fans, blowers, compressors and pressure vessels.

16. The system for cooling electronic devices according to claim 2, wherein
the first cooling fluid has an initial temperature T₁ᵢ; and
the second cooling fluid has an initial temperature T₂ᵢ, wherein the expression T₁ᵢ≧T₂ᵢ is satisfied.

17. The system for cooling electronic devices according to claim 2, wherein
the first cooling fluid and the second cooling fluid are both air.

18. A method of cooling components mounted on a circuit pack assembly within an equipment shelf comprising:
moving a first cooling fluid over a major surface of the circuit pack assembly to remove a quantity of heat generated by a plurality of components;
directing a stream of a second cooling fluid through a nozzle assembly and onto a surface of a targeted component to remove an additional quantity of heat generated by the targeted component.

19. The method of cooling components mounted on a circuit pack assembly within an equipment shelf according to claim 18, further comprising:
monitoring a temperature of the targeted component;
generating an overtemp signal when the temperature of the targeted component exceeds a preset temperature limit; and
initiating at least one remedial actions.

20. The method of cooling components mounted on a circuit pack assembly within an equipment shelf according to claim 19, wherein
the remedial action includes directing a stream of third cooling fluid onto a surface of the targeted component to provide additional cooling.

21. The method of cooling components mounted on a circuit pack assembly within an equipment shelf according to claim 20, wherein
the third cooling fluid cools the targeted component by evaporation.

22. The method of cooling components mounted on a circuit pack assembly within an equipment shelf according to claim 18, wherein:
the first cooling fluid and the second cooling fluid are both air.
